(19) United States
(12) Patent Application Publication
(10) Pub. No.: US 2008/0198561 A1
(43) Pub. Date: Aug. 21, 2008

(54) HIGH-FREQUENCY SIGNAL PROCESSING MODULE AND ELECTRONIC DEVICE

(76) Inventor: Koji OIWA, Osaka (JP)

Correspondence Address: BIRCH STEWART KOLASCH & BIRCH, PO BOX 747, FALLS CHURCH, VA, 22040-0747, US

(21) Appl. No.: 11/943,368

(22) Filed: Nov. 20, 2007

(30) Foreign Application Priority Data
Feb. 19, 2007 (JP) 2007-037494

(51) Int. Cl. H05K 1/18

(52) U.S. Cl. 361/740

(57) ABSTRACT

A high-frequency signal processing module has: a module base having a recess and a first connection terminal connectable to an external circuit board arranged on the open side of the recess; and a high-frequency signal processing circuit processing a high-frequency signal. The high-frequency signal processing circuit has a second connection terminal connectable to the external circuit board arranged on the open side of the recess of the module base, and is housed inside the recess of the module base. In this high-frequency signal processing module, the signal path along which a high-frequency signal fed through the external circuit board is received by the high-frequency signal processing circuit is short, contributing to a reduced parasitic inductive component.

This nonprovisional application claims priority under 35 U.S.C. § 119(a) on Patent Application No. 2007-037494 filed in Japan on Feb. 19, 2007, the entire contents of which are hereby incorporated by reference.

### BACKGROUND OF THE INVENTION

1. Field of the Invention

The present invention relates to a high-frequency signal processing module that processes a high-frequency signal, and to an electronic device incorporating such a high-frequency signal processing module.

2. Description of Related Art

As one form of digital terrestrial television broadcast, for example in Japan, a broadcast service called “One Seg” was launched in April, 2006 which uses, of the 13 segments of an analog television broadcast channel, the one set aside for mobile devices (such as mobile phones and mobile terminals). Using a mobile device such as a mobile phone that is ready for One Seg broadcasts, a user can view the same broadcast programs as through ordinary digital terrestrial television broadcast, and can also use data broadcast contents prepared exclusively for One Seg broadcasts.

Other known digital broadcast systems for mobiles devices are, to name a few: DVB-H (digital video broadcasting for handheld); Media FLO; TDMB (terrestrial digital multimedia broadcasting); SDMB (satellite digital multimedia broadcast); and DMB-T (digital multimedia broadcasting-terrestrial).

Mobile devices ready for these digital broadcasts incorporate a high-frequency signal processing module, which comprises: a high-frequency signal processing circuit that processes a high-frequency signal as by selecting a television signal, corresponding to a given channel, transmitted from a broadcast station; and a digital signal processing circuit that processes a digital signal as by demodulating a modulated digital signal into a TS (transport stream) signal such as one conforming to MPEG.

Now a description will be given of a conventional high-frequency signal processing module comprising a high-frequency signal processing circuit and a digital signal processing circuit. FIG. 5 is a side sectional view showing an outline of the structure of a conventional high-frequency signal processing module 90 comprising a high-frequency signal processing circuit and a digital signal processing circuit. In FIG. 5, the high-frequency signal processing module 90 is used as a component of an electronic device, and is connected to a main circuit board 99 provided in it that has a signal path of a high-frequency signal formed on it.

The high-frequency signal processing module 90 includes: a module base 91 having a recess 91a open downward and a first connection terminal surface 91b connected to a main circuit board 99 arranged on the open side of the recess 91a; a high-frequency signal processing circuit 92 connected to the top of the module base 91; and a digital signal processing circuit 93 connected to the top end of the recess 91a.

On the other hand, JP-A-H9-283693 discloses a high-frequency semiconductor device having a ground conductor formed in the topmost layer of a circuit board formed of multiple layers of dielectric films laid together.

Inconveniently, the conventional high-frequency signal processing module 90 shown in FIG. 5 has the following disadvantages. Since the high-frequency signal processing circuit 92 is connected to the top of the module base 91, a high-frequency signal fed through the main circuit board 99 is received by the high-frequency signal processing circuit 92 through the module base 91 as indicated by arrow α. Thus, the high-frequency signal needs to travel a very long path before being received by the high-frequency signal processing circuit 92, and this causes degradation in sensitivity. Moreover, in a case where, to make the module base 91 compact, the signal path through the module base 91 is formed as a small-diameter through hole, a parasitic inductive component appears, and this causes degradation in sensitivity.

Even by use of the technology disclosed in JP-A-H9-283693 mentioned above, the above-mentioned disadvantages of the conventional high-frequency signal processing module 90 shown in FIG. 5 cannot be overcome.

### SUMMARY OF THE INVENTION

In view of the inconveniences discussed above, it is an object of the present invention to provide a high-frequency signal processing module that comprises: a module base having a recess and a first connection terminal connectable to an external circuit board arranged on the open side of the recess; and a high-frequency signal processing circuit processing a high-frequency signal, wherein the signal path along which a high-frequency signal fed through the external circuit board is received by the high-frequency signal processing circuit is short, contributing a reduced parasitic inductive component. It is another object of the present invention to provide an electronic device incorporating such a high-frequency signal processing module.

To achieve the above objects, according to one aspect of the present invention, a high-frequency signal processing module is provided with: a module base having a recess and a first connection terminal connectable to an external circuit board arranged on the open side of the recess; and a high-frequency signal processing circuit processing a high-frequency signal. Here, the high-frequency signal processing circuit has a second connection terminal connectable to the external circuit board arranged on the open side of the recess of the module base, and is housed inside the recess of the module base.

With this structure, a high-frequency signal fed through the external circuit board is received by the high-frequency signal processing circuit directly from the external circuit board. Thus, the signal path along which the high-frequency signal fed through the external circuit board is received by the high-frequency signal processing circuit is very short, contributing to the prevention of degradation in sensitivity. Moreover, the signal path along which the high-frequency signal fed through the external circuit board travels does not include a signal path using a small-diameter through hole. This helps prevent degradation in sensitivity due to a parasitic inductive component.

In the structure described above, a digital signal processing circuit connected to the module base outside the recess of the module base may additionally be provided, and the module base and the high-frequency signal processing circuit do not may make contact with each other.

With this structure, a digital signal seldom leaks from the digital signal processing circuit into the high-frequency signal processing circuit. Thus, the high-frequency signal processing module according to the present invention can include a digital signal processing circuit required in an electronic device ready for digital broadcasts but can nevertheless prevent degradation in sensitivity due to leakage of a digital signal from the digital signal processing circuit into the high-frequency signal processing circuit as occurs, in the conventional high-frequency signal processing module 90 shown in FIG. 5, as a result of both the high-frequency signal processing circuit 92 and the digital signal processing circuit 93 being connected to the module base 91 (see arrow β in FIG. 5).

In the structure described above, a securing member securing the high-frequency signal processing circuit in a fixed position inside the recess of the module base may additionally be provided. With this structure, it is possible to prevent various troubles such as degradation in sensitivity as occur if the high-frequency signal processing circuit is arranged in an unstable position.

In the structure described above, the securing member may be an insulating sheet arranged between the module base and the high-frequency signal processing circuit. With this structure, it is possible to secure the high-frequency signal processing circuit in a fixed position inside the recess of the module base and in addition prevent degradation in sensitivity resulting from a digital signal leaking from the digital signal processing circuit into the high-frequency signal processing circuit.

Using an insulating sheet of an adhesive material makes it easy to secure the high-frequency signal processing circuit in a fixed position. Using an insulating sheet of a soft material (such as urethane), by contrast, helps prevent, with the shock absorbing property of the insulating sheet, deterioration of the module base and the high-frequency signal processing circuit caused by an external factor such as shock, and also helps prevent, with the elasticity of the insulating sheet, bad contact between the module base and the high-frequency signal processing circuit even if the parallelism between them is lost for some cause.

In the structure described above, the securing member may be resin injected into the recess of the module base. With this structure, it is possible to prevent troubles such as deterioration of the module base and the high-frequency signal processing circuit caused by an external factor such as shock. Moreover, using insulating resin helps prevent degradation in sensitivity resulting from a digital signal leaking from the digital signal processing circuit into the high-frequency signal processing circuit.

According to another aspect of the present invention, a high-frequency signal processing module is provided with: a module base connected to an external circuit board; a high-frequency signal processing circuit connected to the external circuit board; and a digital signal processing circuit. Here, the module base has a recess open at one face thereof, and this one face of the module base is connected to the external circuit board so that the high-frequency signal processing circuit connected to the external circuit board is housed inside the recess. Moreover, the digital signal processing circuit is connected to the face of the module base opposite from that one face.

According to yet another aspect of the present invention, an electronic device is provided with the high-frequency signal processing modules structured as described above, and is additionally provided with a main circuit board having a signal path of a high-frequency signal. Here, the first and second connection terminals are individually connected to the main circuit board.

In the above structure, the high-frequency signal processing circuit may be a semiconductor integrated circuit, and the second connection terminal may be connected to the main circuit board by flip-chip connection. With this structure, the distance between the high-frequency signal processing circuit and the main circuit board can be made shorter than in a case where connection is achieved with a bonding wire or lead frame, and the formation of a parasitic inductive component can be suppressed. Thus, it is possible to prevent degradation in sensitivity.

In the above structure, the gap between the second connection terminal and the main circuit board may be filled with underfill resin. With this structure, it is possible to prevent deterioration caused by an external factor such as shock as may arise in a case where the second connection terminal is connected to the main circuit board by flip-chip connection.

### BRIEF DESCRIPTION OF THE DRAWINGS

These and other objects and features of the present invention will be apparent from the following detailed description of preferred embodiments thereof taken in conjunction with the accompanying drawings, in which:

FIG. 1 is a side sectional view showing an outline of the structure of a high-frequency signal processing module 10;

FIG. 2 is a diagram illustrating the procedure by which the high-frequency signal processing module 10 is connected to a main circuit board 19;

FIG. 3 is a side sectional view showing an outline of the structure of the high-frequency signal processing module 10 as observed in a case in which a second connection terminal surface 12a is connected to the main circuit board 19 by flip-chip connection;

FIG. 4 is a side sectional view showing an outline of the structure of the high-frequency signal processing module 10 as observed in a case in which it is provided with an insulating sheet 15; and

FIG. 5 is a side sectional view showing an outline of the structure of a high-frequency signal processing module 90.

### DETAILED DESCRIPTION OF PREFERRED EMBODIMENTS

Hereinafter, an embodiment of the present invention will be described with reference to the accompanying drawings.

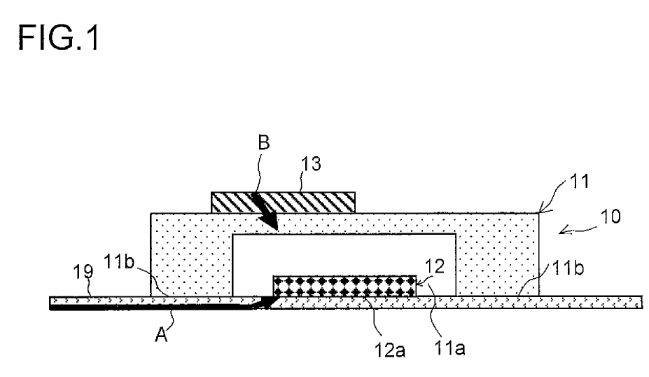

FIG. 1 is a side sectional view showing an outline of the structure of a high-frequency signal processing module 10 embodying the present invention. In FIG. 1, the high-frequency signal processing module 10 is used as a component of an electronic device, and is connected to a main circuit board 19 (external circuit board) provided in it that has a signal path of a high-frequency signal formed on it.

The high-frequency signal processing module 10 includes: a module base 11 having a recess 11a open downward and a first connection terminal surface 11b connected to a main circuit board 19 arranged on the open side of the recess 11a; a high-frequency signal processing circuit 12 having a second connection terminal surface 12a connected by some means to the main circuit board 19 arranged on the open side of the recess 11a of the module base 11, the high-frequency signal processing circuit 12 being housed inside the recess 11a of the module base 11; and a digital signal processing circuit 13 connected to the top of the module base 11. Here, the module base 11 and the high-frequency signal processing circuit 12 do not make contact with each other. The means by which the second connection terminal surface 12a of the high-frequency signal processing circuit 12 is connected to the main circuit board 19 will be described in detail later.

In the high-frequency signal processing module 10 structured as described above, the high-frequency signal processing circuit 12 has a second connection terminal surface 12a connected to the main circuit board 19 arranged on the open side of the recess 11a of the module base 11, and is housed inside the recess 11a of the module base 11. Thus, a high-frequency signal fed through the main circuit board 19 is received by the high-frequency signal processing circuit 12 directly from the main circuit board 19 as indicated by arrow A. Accordingly, the signal path along which the high-frequency signal fed through the main circuit board 19 is received by the high-frequency signal processing circuit 12 is very short, contributing to the prevention of degradation in sensitivity. Moreover, the signal path along which the high-frequency signal fed through the main circuit board 19 travels does not include a signal path using a small-diameter through hole formed in the module base 11. Thus, it is possible to prevent degradation in sensitivity due to a parasitic inductive component.

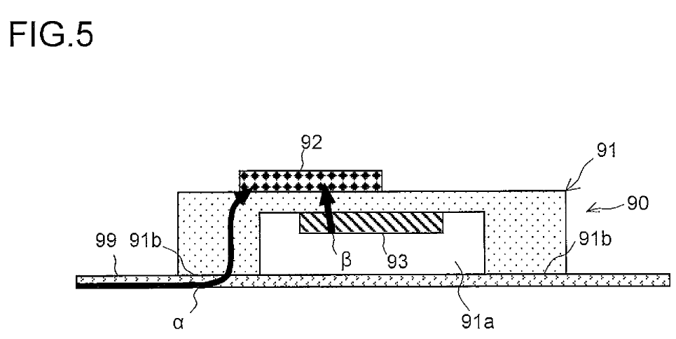

The high-frequency signal processing module 10 further includes a digital signal processing circuit 13 connected to the top of the module base 11, and the module base 11 and the high-frequency signal processing circuit 12 do not make contact with each other. Thus, a digital signal seldom leaks from the digital signal processing circuit 13 into the high-frequency signal processing circuit 12 as indicated by arrow B. Thus, the high-frequency signal processing module 10 can include a digital signal processing circuit 13 required in an electronic device ready for digital broadcasts but can nevertheless prevent degradation in sensitivity due to leakage of a digital signal from the digital signal processing circuit into the high-frequency signal processing circuit as occurs, in the conventional high-frequency signal processing module 90 shown in FIG. 5, as a result of both the high-frequency signal processing circuit 92 and the digital signal processing circuit 93 being connected to the module base 91 (see arrow β in FIG. 5).

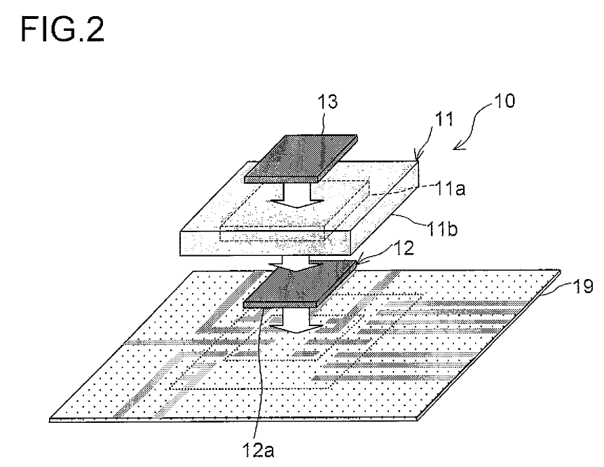

Next, the procedure by which the high-frequency signal processing module 10 and the main circuit board 19 are connected together will be described. FIG. 2 is a diagram illustrating the procedure by which the high-frequency signal processing module 10 is connected to the main circuit board 19. To connect the high-frequency signal processing module 10 to the main circuit board 19, as shown in FIG. 2, first the second connection terminal surface 12a of the high-frequency signal processing circuit 12 is connected to the main circuit board 19; then the first connection terminal surface 11b of the module base 11 is connected to the main circuit board 19 so that the high-frequency signal processing circuit 12 is housed inside the recess 11a of the module base 11; lastly the digital signal processing circuit 13 is connected to the top of the module base 11.

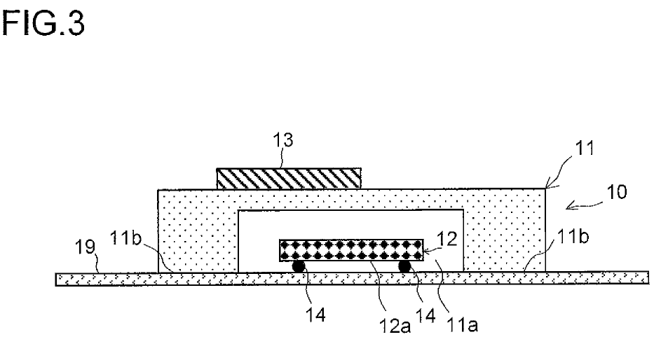

Next, with regard to a case in which the high-frequency signal processing circuit 12 is a semiconductor integrated circuit, the means by which the second connection terminal surface 12a is connected to the main circuit board 19 will be described in detail. FIG. 3 is a side sectional view showing an outline of the structure of the high-frequency signal processing module 10 as observed in a case in which the second connection terminal surface 12a is connected to the main circuit board 19 by flip-chip connection. Here, the second connection terminal surface 12a of the high-frequency signal processing circuit 12 is connected to the main circuit board 19 by solder bumps 14 formed directly on the second connection terminal surface 12a.

Connecting the second connection terminal surface 12a of the high-frequency signal processing circuit 12 to the main circuit board 19 by flip-chip connection in this way helps make the distance between the high-frequency signal processing circuit 12 and the main circuit board 19 shorter than in a case where the connection is achieved by a bonding wire or lead frame, and also helps reduce the formation of a parasitic inductive component. Thus, it is possible to prevent degradation in sensitivity.

Inconveniently, however, since the second connection terminal surface 12a of the high-frequency signal processing circuit 12 is connected to the main circuit board 19 by small solder bumps 14 formed directly on the second connection terminal surface 12a, deterioration may arise from an external factor such as shock. To avoid this, it is preferable that the gap between the second connection terminal surface 12a of the high-frequency signal processing circuit 12 and the main circuit board 19 be filled with underfill resin.

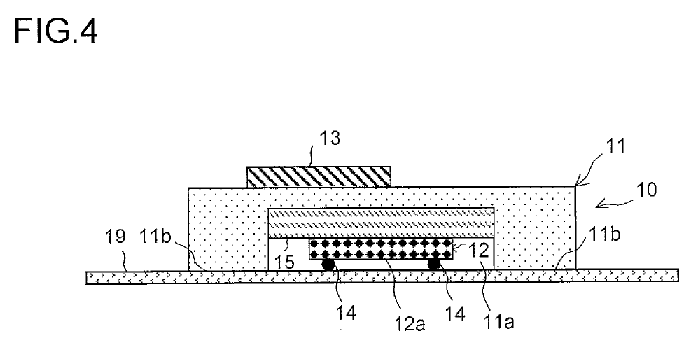

Moreover, to prevent various troubles such as degradation in sensitivity as occur if the high-frequency signal processing circuit 12 is arranged in an unstable position, it is preferable that the high-frequency signal processing module 10 be additionally provided with a securing member that secures the high-frequency signal processing circuit 12 in a fixed position inside the recess 11a of the module base 11. FIG. 4 is a side sectional view showing an outline of the structure of the high-frequency signal processing module 10 as observed in a case in which it is provided with an insulating sheet 15 (securing member) arranged between the module base 11 and the high-frequency signal processing circuit 12.

Arranging an insulating sheet 15 as a securing member between the module base 11 and high-frequency signal processing circuit 12 in this way helps secure the high-frequency signal processing circuit 12 in a fixed position inside the recess 11a of the module base 11, and in addition helps prevent degradation in sensitivity resulting from a digital signal leaking from the digital signal processing circuit 13 into the high-frequency signal processing circuit 12.

The insulating sheet 15 may be, for example, one of an adhesive material or one of a soft material. Using an insulating sheet 15 of an adhesive material makes it easy to secure the high-frequency signal processing circuit 12 in a fixed position. Using an insulating sheet 15 of a soft material (such as urethane), by contrast, helps prevent, with the shock absorbing property of the insulating sheet 15, deterioration of the module base 11 and the high-frequency signal processing circuit 12 caused by an external factor such as shock, and also helps prevent, with the elasticity of the insulating sheet 15, bad contact between the module base 11 and the high-frequency signal processing circuit 12 even if the parallelism between them is lost for some cause.

In the high-frequency signal processing module 10, the securing member may be resin injected into the recess 11a of the module base 11. This too helps prevent troubles such as deterioration of the module base 11 and the high-frequency signal processing circuit 12 caused by an external factor such as shock. Using insulating resin here helps prevent degradation in sensitivity resulting from a digital signal leaking from the digital signal processing circuit 13 into the high-frequency signal processing circuit 12.

It should be understood that the present invention may be practiced otherwise than specifically described by way of an embodiment above and that many variations and modifications are possible within the spirit of the invention. For example, although the embodiment above deals with a case in which the first connection terminal surface 11b of the module base 11 is connected to the main circuit board 19 so that the recess 11a is open downward, it is also possible to make the recess 11a open upward.

As described above, in the high-frequency signal processing module according to the embodiment, the high-frequency signal processing circuit has a second connection terminal surface connectable to an external circuit board arranged on the open side of the recess of the module base, and is housed inside the recess of the module base. Thus, a high-frequency signal fed through the external circuit board is received by the high-frequency signal processing circuit directly from the external circuit board. Accordingly, the signal path along which the high-frequency signal fed through the external circuit board is received by the high-frequency signal processing circuit is very short, contributing to the prevention of degradation in sensitivity. Moreover, the signal path along which the high-frequency signal fed through the external circuit board travels does not include a signal path using a small-diameter through hole formed in the module base. Thus, it is possible to prevent degradation in sensitivity due to a parasitic inductive component.

Moreover, the high-frequency signal processing module according to the embodiment includes a digital signal processing circuit connected to the module base outside the recess of the module base, and the module base and the high-frequency signal processing circuit do not make contact with each other. Thus, a digital signal seldom leaks from the digital signal processing circuit into the high-frequency signal processing circuit. Thus, the high-frequency signal processing module according to the embodiment can include a digital signal processing circuit required in an electronic device ready for digital broadcasts but can nevertheless prevent degradation in sensitivity due to leakage of a digital signal from the digital signal processing circuit into the high-frequency signal processing circuit as occurs, in the conventional high-frequency signal processing module 90 shown in FIG. 5, as a result of both the high-frequency signal processing circuit 92 and the digital signal processing circuit 93 being connected to the module base 91 (see arrow P in FIG. 5).

Moreover, the high-frequency signal processing module according to the embodiment includes a securing member that secures the high-frequency signal processing circuit in a fixed position inside the recess of the module base. This helps prevent various troubles such as degradation in sensitivity as occur if the high-frequency signal processing circuit is arranged in an unstable position.

Arranging as the securing member an insulating sheet between the module base and the high-frequency signal processing circuit helps secure the high-frequency signal processing circuit in a fixed position inside the recess of the module base and in addition prevent degradation in sensitivity resulting from a digital signal leaking from the digital signal processing circuit into the high-frequency signal processing circuit.

Using an insulating sheet of an adhesive material makes it easy to secure the high-frequency signal processing circuit in a fixed position. Using an insulating sheet of a soft material (such as urethane), by contrast, helps prevent, with the shock absorbing property of the insulating sheet, deterioration of the module base and the high-frequency signal processing circuit caused by an external factor such as shock, and also helps prevent, with the elasticity of the insulating sheet, bad contact between the module base and the high-frequency signal processing circuit even if the parallelism between them is lost for some cause.

Using, as the securing member, resin injected into the recess of the module base helps prevent troubles such as deterioration of the module base and the high-frequency signal processing circuit caused by an external factor such as shock. Using insulating resin here helps prevent degradation in sensitivity resulting from a digital signal leaking from the digital signal processing circuit into the high-frequency signal processing circuit.

In the electronic device according to the embodiment, the high-frequency signal processing circuit is a semiconductor integrated circuit, and the second connection terminal surface and the main circuit board are connected together by flip-chip connection. This helps make the distance between the high-frequency signal processing circuit and the main circuit board shorter than in a case where connection is achieved with a bonding wire or lead frame, and also helps reduce the formation of a parasitic inductive component. Thus, it is possible to prevent degradation in sensitivity.

Moreover, in the electronic device according to the embodiment, the gap between the second connection terminal and the main circuit board is filled with underfill resin. This helps prevent deterioration caused by an external factor such as shock as may arise in a case where the second connection terminal is connected to the main circuit board by flip-chip connection.

What is claimed is:

1. A high-frequency signal processing module comprising:
a module base having
a recess and
a first connection terminal connectable to an external circuit board arranged on an open side of the recess; and
a high-frequency signal processing circuit processing a high-frequency signal,
wherein the high-frequency signal processing circuit has a second connection terminal connectable to the external circuit board arranged on the open side of the recess of the module base, and is housed inside the recess of the module base.

2. The high-frequency signal processing module according to claim 1, further comprising:
a digital signal processing circuit connected to the module base outside the recess of the module base,
wherein the module base and the high-frequency signal processing circuit do not make contact with each other.

3. The high-frequency signal processing module according to claim 1, further comprising:
a securing member securing the high-frequency signal processing circuit in a fixed position inside the recess of the module base.

4. The high-frequency signal processing module according to claim 3,
wherein the securing member is an insulating sheet arranged between the module base and the high-frequency signal processing circuit.

5. The high-frequency signal processing module according to claim 3,
wherein the securing member is resin injected into the recess of the module base.

6. A high-frequency signal processing module comprising:
a module base connected to an external;
a high-frequency signal processing circuit connected to the external circuit board; and
a digital signal processing circuit,
wherein the module base has a recess open at one face thereof, and said one face of the module base is connected to the external circuit board so that the high-frequency signal processing circuit connected to the external circuit board is housed inside the recess, and
wherein the digital signal processing circuit is connected to a face of the module base opposite from said one face.

7. An electronic device comprising the high-frequency signal processing module according to any one of claims 1 to 5, further comprising:
a main circuit board having a signal path of a high-frequency signal,
wherein the first and second connection terminals are individually connected to the main circuit board.

8. The electronic device according to claim 7,
wherein the high-frequency signal processing circuit is a semiconductor integrated circuit, and
wherein the second connection terminal is connected to the main circuit board by flip-chip connection.

9. The electronic device according to claim 8,
wherein a gap between the second connection terminal and the main circuit board is filled with underfill resin.
